(19) United States
(12) Patent Application Publication
(10) Pub. No.: US 2023/0260886 A1
(43) Pub. Date: Aug. 17, 2023

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: Feng Kao, Taichung City (TW); Lung-Yuan Wang, Taichung City (TW)

(73) Assignee: SILICONWARE PRECISION INDUSTRIES CO., LTD., Taichung City (TW)

(21) Appl. No.: 17/726,163

(22) Filed: Apr. 21, 2022

(30) Foreign Application Priority Data
Feb. 16, 2022 (TW) 111105614

(51) Int. Cl. H01L 23/498; H01L 23/367; H01L 21/48; H01L 23/14

(52) U.S. Cl. CPC H01L 23/49833; H01L 21/4857; H01L 23/145; H01L 23/3675; H01L 23/49816; H01L 23/49822; H01L 23/49838; H01L 25/0655

(57) ABSTRACT

An electronic package is provided, in which a circuit structure is disposed on the uppermost side of a plurality of stacked organic material substrates for connecting an electronic element, so that a line width/line spacing of a redistribution layer of the circuit structure conforms with a line width/line spacing of the electronic element. Therefore, when the size specification of the electronic element is designed to be miniaturized, the redistribution layer configured in the circuit structure can effectively match the line spacing/line width of the electronic element, so as to meet the requirements of miniaturized packaging.

### BACKGROUND

### 1. Technical Field

The present disclosure relates to a semiconductor packaging process, and more particularly, to an electronic package and a manufacturing method thereof.

### 2. Description of Related Art

With the vigorous development of portable electronic products in recent years, various related products are also gradually developing towards the trend of high density, high performance, lightness, thinness, shortness and smallness.

As shown in FIG. 1, a conventional semiconductor package 1 is manufactured by first arranging a semiconductor chip 11 with its active surface 11a on a package substrate 10 made of ABF (Ajinomoto Build-up Film) by flip-chip bonding (i.e., via conductive bumps 110 and an underfill 111), then bonding a heat sink 13 with its top sheet 130 onto an inactive surface 11b of the semiconductor chip 11 by means of a heat dissipation glue 12, and mounting supporting legs 131 of the heat sink 13 on the package substrate 10 via an adhesive layer 14. Next, an encapsulation molding operation is performed, so that an encapsulation gel (not shown) covers the semiconductor chip 11 and the heat sink 13, and the top sheet 130 of the heat sink 13 is exposed from the encapsulation gel. Afterwards, the package substrate 10 is arranged on a circuit board.

However, in the conventional semiconductor package 1, when the size specification of the semiconductor chip 11 is designed to be miniaturized, the line spacing/line width of the integrated circuit of the semiconductor chip 11 is also reduced accordingly. As a result, the circuits configured on the conventional ABF type package substrate 10 cannot match the line spacing/line width of the semiconductor chip 11, so it is difficult to realize the requirement of miniaturized packaging.

Furthermore, because the size of the package substrate 10 will be larger and larger according to the increase in the functional requirements of the semiconductor chip 11, and the number of circuit layers configured therein will also be higher and higher, the process yield of the package substrate 10 is also reduced (i.e., the more layers, the greater the error), thereby causing the production cost and production time of the package substrate 10 to increase rapidly.

Therefore, how to overcome the above-mentioned drawbacks of the prior art has become an urgent issue to be solved at present.

### SUMMARY

In view of the various deficiencies of the prior art, the present disclosure provides an electronic package, comprising: a circuit structure provided with a redistribution layer and having a first surface and a second surface opposite to each other; at least one electronic element disposed on the first surface of the circuit structure and electrically connected to the redistribution layer; a first organic material substrate disposed on the second surface of the circuit structure and having a first circuit layer; and at least one second organic material substrate having a second circuit layer, wherein the first organic material substrate is stacked on the at least one second organic material substrate via a plurality of supporting bodies, such that the redistribution layer is electrically connected to the second circuit layer via the first circuit layer, and wherein a line width or line spacing of the redistribution layer of the circuit structure is smaller than a line width or line spacing of the first circuit layer of the first organic material substrate and a line width or line spacing of the second circuit layer of the at least one second organic material substrate.

The present disclosure also provides an electronic package, comprising: a circuit structure provided with a redistribution layer and having a first surface and a second surface opposite to each other; at least one electronic element disposed on the first surface of the circuit structure and electrically connected to the redistribution layer; a first organic material substrate disposed on the second surface of the circuit structure and having a first circuit layer; and at least one second organic material substrate having a second circuit layer, wherein the first organic material substrate is stacked on the at least one second organic material substrate via a plurality of supporting bodies, such that the redistribution layer is electrically connected to the second circuit layer via the first circuit layer, and wherein a coefficient of thermal expansion of the at least one second organic material substrate is greater than a coefficient of thermal expansion of the circuit structure and a coefficient of thermal expansion of the first organic material substrate.

The present disclosure also provides a method of manufacturing an electronic package, comprising: providing a circuit structure with a redistribution layer, a first organic material substrate with a first circuit layer and at least one second organic material substrate with a second circuit layer, wherein the circuit structure has a first surface and a second surface opposite to each other, and a line width or line spacing of the redistribution layer of the circuit structure is smaller than a line width or line spacing of the first circuit layer of the first organic material substrate and a line width or line spacing of the second circuit layer of the at least one second organic material substrate; disposing at least one electronic element on the first surface of the circuit structure and electrically connecting the at least one electronic element to the redistribution layer, and disposing the first organic material substrate on the second surface of the circuit structure; and stacking the first organic material substrate on the at least one second organic material substrate via a plurality of supporting bodies, wherein the redistribution layer is electrically connected to the second circuit layer via the first circuit layer.

The present disclosure also provides a method of manufacturing an electronic package, comprising: providing a circuit structure with a redistribution layer, a first organic material substrate with a first circuit layer and at least one second organic material substrate with a second circuit layer, wherein the circuit structure has a first surface and a second surface opposite to each other, and a coefficient of thermal expansion of the at least one second organic material substrate is greater than a coefficient of thermal expansion of the circuit structure and a coefficient of thermal expansion of the first organic material substrate; disposing at least one electronic element on the first surface of the circuit structure and electrically connecting the at least one electronic element to the redistribution layer, and disposing the first organic material substrate on the second surface of the circuit structure; and stacking the first organic material substrate on the at least one second organic material substrate via a plurality of supporting bodies, wherein the redistribution layer is electrically connected to the second circuit layer via the first circuit layer.

In the aforementioned electronic package and the manufacturing method thereof, a width of the circuit structure is smaller than a width of the first organic material substrate.

In the aforementioned electronic package and the manufacturing method thereof, the first organic material substrate is stacked with a plurality of the second organic material substrates, and the line width or line spacing of each of the second organic material substrates increases in a direction away from the circuit structure.

In the aforementioned electronic package and the manufacturing method thereof, the first organic material substrate is stacked with a plurality of the second organic material substrates, and the coefficient of thermal expansion of each of the second organic material substrates increases in a direction away from the circuit structure.

In the aforementioned electronic package and the manufacturing method thereof, a number of layers of the redistribution layer of the circuit structure is smaller than a number of layers of the second circuit layer of the at least one second organic material substrate.

In the aforementioned electronic package and the manufacturing method thereof, a number of layers of the first circuit layer of the first organic material substrate is equal to a number of layers of the second circuit layer of the at least one second organic material substrate.

In the aforementioned electronic package and the manufacturing method thereof, the present disclosure further comprises disposing a heat sink on the first organic material substrate.

In the aforementioned electronic package and the manufacturing method thereof, the plurality of supporting bodies are electrically connected to the first organic material substrate and the at least one second organic material substrate.

In the aforementioned electronic package and the manufacturing method thereof, the present disclosure further comprises providing a circuit board, wherein the at least one second organic material substrate is stacked on the circuit board via a plurality of conductive elements. For example, the plurality of conductive elements are electrically connected to the circuit board and the at least one second organic material substrate.

It can be seen from the above that, in the electronic package and the manufacturing method thereof according to the present disclosure, by configuring a circuit to be bonded to the electronic element in the circuit structure, the line width/line spacing of the redistribution layer is in line with (e.g., conforms with) the line width/line spacing of the electronic element. Therefore, compared with the prior art, when the size specification of the electronic element is designed to be miniaturized and the line spacing/line width of the integrated circuit thereof is also reduced, the redistribution layer configured in the circuit structure can effectively match the line spacing/line width of the electronic element, so as to meet the requirement of miniaturized packaging.

Furthermore, in the manufacturing method of the present disclosure, the expected number of circuit layers (that is, the number of layers of the redistribution layer, the first and second circuit layers) are arranged in the circuit structure and the first and second organic material substrates respectively, so that the number of circuit layers of the circuit structure and the first and second organic material substrates can be controlled within the acceptable yield range, so as to improve the process yield. Therefore, compared with the prior art, the manufacturing method of the present disclosure can effectively reduce the manufacturing cost and manufacturing time of the electronic package.

### BRIEF DESCRIOPTION OF THE DRAWINGS

FIG. 1 is a schematic cross-sectional view of a conventional semiconductor package.

FIGS. 2A to 2B are schematic cross-sectional views illustrating a manufacturing method of an electronic package according to the present disclosure.

FIG. 3 is a schematic cross-sectional view of another embodiment of FIG. 2B.

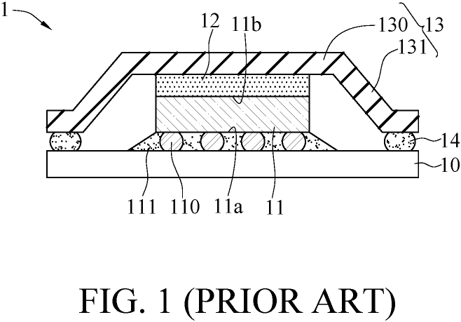

### DETAILED DESCRIPTIONS

The following describes the implementation of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “upper,” “lower,” “inner,” “outer,” “one” and the like used herein are merely used for clear explanation rather than limiting the practicable scope of the present disclosure, and thus, alterations or adjustments of the relative relationships thereof without essentially altering the technical contents should still be considered in the practicable scope of the present disclosure.

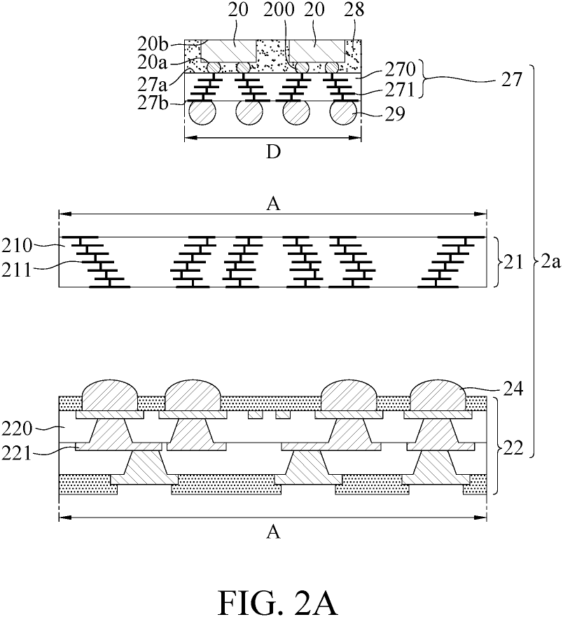

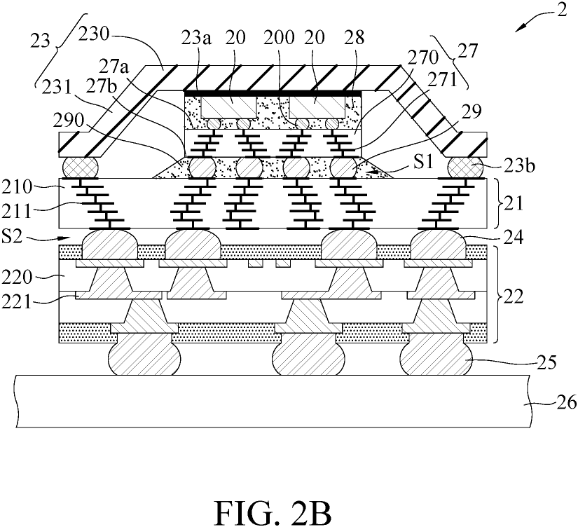

FIGS. 2A to 2B are schematic cross-sectional views illustrating a manufacturing method of an electronic package 2 according to the present disclosure.

As shown in FIG. 2A, a first organic material substrate 21, at least one second organic material substrate 22 and a circuit structure 27 are provided, and at least one electronic element 20 is mounted on the circuit structure 27, so that the electronic element 20 is electrically connected to the circuit structure 27, and an encapsulation layer 28 covers the electronic element 20.

The circuit structure 27 is a carrier without a substrate, such as a coreless carrier, which has a first surface 27a and a second surface 27b opposite to each other, and includes at least one dielectric layer 270 and a redistribution layer (RDL) 271 arranged on the dielectric layer 270, wherein the outermost dielectric layer 270 may be used as a solder mask, and a partial surface of the outermost redistribution layer 271 is exposed from the solder mask.

In an embodiment, the material for forming the redistribution layer 271 is copper, and the material for forming the dielectric layer 270 is a dielectric material such as polybenzoxazole (PBO), polyimide (PI), prepreg (PP) and the like.

It should be understood that the overall composition of the circuit structure 27 is not a conventional silicon interposer, which is hereby described.

The electronic element 20 is an active element, a passive element, or a combination of the active element and the passive element, etc., wherein the active element is such as a semiconductor chip, and the passive element is such as a resistor, a capacitor, or an inductor.

In an embodiment, the electronic element 20 is an active element, which has an active surface 20a and an inactive surface 20b opposite to each other, the active surface 20a has a plurality of electrode pads (not shown), so that the electrode pads are arranged on the first surface 27a of the circuit structure 27 in a flip-chip manner by a plurality of conductive bumps 200 such as solder material and are electrically connected to the redistribution layer 271; alternatively, the electronic element 20 may have its inactive surface 20b arranged on the first surface 27a of the circuit structure 27, and the electrode pads may be electrically connected to the redistribution layer 271 in a wire-bonding manner by a plurality of bonding wires (not shown); alternatively, the electronic element 20 may directly contact the redistribution layer 271 to electrically connect the redistribution layer 271. However, the manner in which the electronic element 20 is electrically connected to the circuit structure 27 is not limited to the above.

The first organic material substrate 21 is a circuit structure with a core layer or without a core layer (coreless), such as a package substrate, which includes at least one first insulating layer 210 and a first circuit layer 211 arranged on the first insulating layer 210.

In an embodiment, a fan-out first circuit layer 211 is formed by making an RDL, the material of which is copper, and the material of which the first insulating layer 210 is formed is a dielectric material such as ABF (Ajinomoto Build-up Film), polybenzoxazole (PBO), polyimide (PI), prepreg (PP) and the like.

Furthermore, a width D (or layout area) of the circuit structure 27 is smaller than a width A (or layout area) of the first organic material substrate 21.

The second organic material substrate 22 is a Substrate Like PCB (SLP), which includes at least one second insulating layer 220 and a second circuit layer 221 arranged on the second insulating layer 220.

In an embodiment, the second circuit layer 221 is formed in a build-up circuit manner, and its material is copper, and the material for forming the second insulating layer 220 is a dielectric material such as polybenzoxazole (PBO), polyimide (PI), prepreg (PP) and the like, or a solder-proof material such as solder mask and graphite.

Furthermore, a coefficient of thermal expansion (CTE) of the circuit structure 27 is different from a coefficient of thermal expansion of the first organic material substrate 21 and a coefficient of thermal expansion of the second organic material substrate 22. For example, the coefficient of thermal expansion of the circuit structure 27 is smaller than the coefficient of thermal expansion of the first organic material substrate 21, and the coefficient of thermal expansion of the first organic material substrate 21 is smaller than the coefficient of thermal expansion of the second organic material substrate 22.

Alternatively, the line spacing/line width of the circuit structure 27 is different from the line spacing/line width of the first organic material substrate 21 and the line spacing/line width of the second organic material substrate 22. For example, the line spacing/line width of the redistribution layer 271 is smaller than the line spacing/line width of the first circuit layer 211, and the line spacing/line width of the first circuit layer 211 is smaller than the line spacing/line width of the second circuit layer 221.

Furthermore, a number of layers of the first circuit layer 211 of the first organic material substrate 21 can be equal to a number of layers of the second circuit layer 221 of the second organic material substrate 22 according to requirements.

In addition, the width A (or layout area) of the first organic material substrate 21 is the same as a width A (or layout area) of the second organic material substrate 22.

The encapsulation layer 28 is an insulating material, such as polyimide (PI), dry film, an encapsulation gel such as epoxy resin, or molding compound, which can be formed on the circuit structure 27 by lamination or molding.

In an embodiment, a surface of the encapsulation layer 28 can be flush with the inactive surface 20b of the electronic element 20 via a leveling process. For example, the leveling process removes portions of the electronic element 20 and portions of the encapsulation layer 28 by grinding.

Furthermore, the encapsulation layer 28 may cover the conductive bumps 200; alternatively, an underfill (not shown) may first be formed between the electronic element 20 and the circuit structure 27 to cover the conductive bumps 200, and then the encapsulation layer 28 is formed to cover the underfill and the electronic element 20.

As shown in FIG. 2B, the circuit structure 27 with its second surface 27b is stacked on the first organic material substrate 21 by a plurality of conductors 29, and the first organic material substrate 21 is stacked on the second organic material substrate 22 by a plurality of supporting bodies 24, and neither the first organic material substrate 21 nor the second organic material substrate 22 is mounted with a chip, so that spaces S1 and S2 are respectively formed between the circuit structure 27 and the first organic material substrate 21 and between the first organic material substrate 21 and the second organic material substrate 22. After that, a heat sink 23 can be selectively arranged on the first organic material substrate 21.

The conductors 29 are solder balls, copper core balls, or metal members (such as columns, blocks, or needles) such as copper or gold, etc., which electrically connect the circuit structure 27 and the first organic material substrate 21.

In an embodiment, an underfill 290 can be formed between the first organic material substrate 21 and the second surface 27b of the circuit structure 27 to cover the conductors 29.

The supporting bodies 24 are solder balls, copper core balls, or metal members (such as columns, blocks, or needles) such as copper or gold, etc., which electrically connect the first organic material substrate 21 and the second organic material substrate 22.

The heat sink 23 is a metal structure and includes a sheet body 230 and leg portions 231, and the sheet body 230 is bonded onto the inactive surface 20b of the electronic element 20 via a bonding layer 23a, so that the leg portions 231 of the heat sink 23 are mounted on the first organic material substrate 21 (or the first circuit layer 211) by an adhesive layer 23b.

In an embodiment, the bonding layer 23a is made of thermal interface material (TIM), thermally conductive adhesive or other suitable materials, and the adhesive layer 23b is made of insulating glue, conductive glue or other suitable materials.

Furthermore, the second organic material substrate 22 may be mounted onto a circuit board 26 by a plurality of conductive elements 25. For example, the coefficient of thermal expansion of the second organic material substrate 22 is smaller than a coefficient of thermal expansion of the circuit board 26, and the conductive elements 25 are solder balls, copper core balls, or metal members (such as columns, blocks, or needles) such as copper or gold, etc., which electrically connect the circuit board 26 and the second circuit layer 221.

A manufacturing method of the present disclosure is mainly by configuring a circuit expected to be bonded to the electronic element 20 in the circuit structure 27, so that the line width/line spacing of the redistribution layer 271 is in line with (e.g., conforms with) the line width/line spacing of the integrated circuit (or the conductive bumps 200) of the electronic element 20. Then, the circuit structure 27, the first organic material substrate 21 and the second organic material substrate 22 are combined (e.g., stacked) to form a carrier component 2a with the required number of circuit layers. Therefore, compared with the prior art, when the size specification of the electronic element 20 is designed to be miniaturized and the line spacing/line width of the integrated circuit thereof is also reduced, the redistribution layer 271 configured in the circuit structure 27 can effectively match the line spacing/line width of the electronic element 20 to meet the requirements of miniaturized packaging.

Furthermore, even if the size of the carrier component 2a becomes larger and larger according to the increase in the number or functional requirements of the electronic element 20, so that the expected number of circuit layers is higher and higher, it is still possible to arrange the expected number of circuit layers in the circuit structure 27, the first organic material substrate 21 and the second organic material substrate 22 respectively (i.e., the number of layers constituting the redistribution layer 271, the first circuit layer 211 and the second circuit layer 221) to improve a process yield of the carrier component 2a (that is, the number of circuit layers of the circuit structure 27, the first organic material substrate 21 and the second organic material substrate 22 can be controlled within an acceptable yield range). Therefore, compared with the prior art, the present disclosure may effectively reduce the manufacturing cost and manufacturing time of the carrier component 2a.

In addition, in the electronic package 2, the arrangement of each substrate structure (i.e., the circuit structure 27, the first organic material substrate 21 and the second organic material substrate 22) can be arranged in sequence according to the level of the CTE, for example, from top to bottom, the circuit structure 27 with the smallest CTE, the first organic material substrate 21, and the second organic material substrate 22 with the largest CTE (the CTE of which is between the CTE of the first organic material substrate 21 and the CTE of the circuit board 26), so that the CTE gradually increases from top to bottom. Therefore, compared with the prior art, in the manufacturing method of the present disclosure, when the CTE of the circuit board 26 remains unchanged, the second organic material substrate 22 can buffer an overall thermal expansion deformation of the carrier component 2a to avoid an issue that the carrier component 2a and the circuit board 26 are separated from each other due to a mismatch of CTE, that is, an issue of a connection reliability of the conductive elements 25 is avoided, so that the second organic material substrate 22 can be effectively electrically connected to the circuit board 26 or the carrier component 2a can pass a reliability test, thereby improving the product yield.

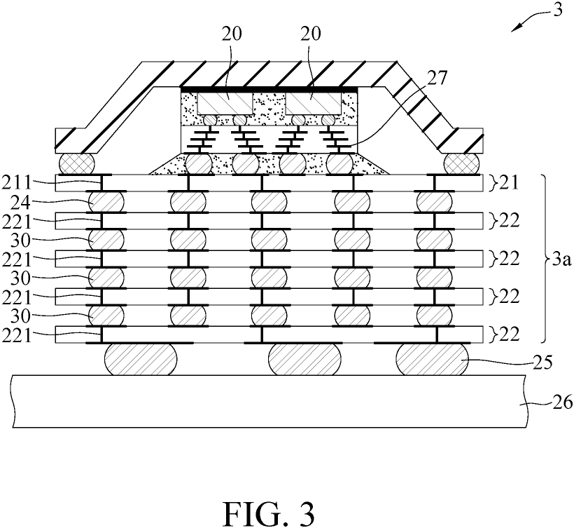

In another embodiment, for an electronic package 3 shown in FIG. 3, a carrier component 3a may also include a plurality of second organic material substrates 22 according to yield requirements, and each of the second organic material substrates 22 is stacked on each other by a plurality of supporting members 30. For example, the coefficient of thermal expansion of each of the second organic material substrates 22 may be the same or different, and the supporting members 30 are solder balls, copper core balls, or metal members (such as columns, blocks, or needles) such as copper or gold, etc., which are electrically connected to the circuit board 26 and each of the second organic material substrates 22. Preferably, the line width/line spacing (or the coefficient of thermal expansion) of each of the second organic material substrates 22 may increase in a direction away from the circuit structure 27.

Therefore, in the electronic package 3, the arrangement of each of the second organic material substrates 22 can be from top to bottom in order from the smallest CTE to the largest CTE, so that the CTE of the second organic material substrates 22 gradually increases from top to bottom. Therefore, compared with the prior art, in the manufacturing method of the present disclosure, when the CTE of the circuit board 26 remains unchanged, the second organic material substrate 22 closest to the circuit board 26 (or farthest from the circuit structure 27) can buffer an overall thermal expansion deformation of the carrier component 3a to avoid an issue that the carrier component 3a and the circuit board 26 are separated from each other due to a mismatch of CTE, so that the second organic material substrate 22 can be effectively electrically connected to the circuit board 26 or the carrier component 3a can pass a reliability test, thereby improving the product yield.

The present disclosure further provides an electronic package 2, 3, which includes: a circuit structure 27, at least one electronic element 20, a first organic material substrate 21 and at least one second organic material substrate 22.

The circuit structure 27 has a first surface 27a and a second surface 27b opposite to each other and includes at least one redistribution layer 271.

The electronic element 20 is arranged on the first surface 27a of the circuit structure 27 and is electrically connected to the redistribution layer 271.

The first organic material substrate 21 is arranged on the second surface 27b of the circuit structure 27 and has a first circuit layer 211, wherein a line width/line spacing of the redistribution layer 271 of the circuit structure 27 is smaller than a line width/line spacing of the first circuit layer 211 of the first organic material substrate 21 and a line width/line spacing of the second circuit layer 221 of the second organic material substrate 22, alternatively, a coefficient of thermal expansion of the second organic material substrate 22 is greater than a coefficient of thermal expansion of the circuit structure 27 and a coefficient of thermal expansion of the first organic material substrate 21.

The second organic material substrate 22 has a second circuit layer 221, and the first organic material substrate 21 is stacked on the second organic material substrate 22 via a plurality of supporting bodies 24, so that the redistribution layer 271 is electrically connected to the second circuit layer 221 via the first circuit layer 211.

In one embodiment, a width D of the circuit structure 27 is smaller than a width A of the first organic material substrate 21.

In one embodiment, the first organic material substrate 21 is stacked with a plurality of the second organic material substrates 22 via a plurality of supporting members 30, and the line width/line spacing of each of the second organic material substrates 22 increases in a direction away from the circuit structure 27.

In one embodiment, the first organic material substrate 21 is stacked with a plurality of the second organic material substrates 22 via a plurality of supporting members 30, and a coefficient of thermal expansion of each of the second organic material substrates 22 increases in a direction away from the circuit structure 27.

In one embodiment, a number of layers of the redistribution layer 271 of the circuit structure 27 is smaller than a number of layers of the second circuit layer 221 of the second organic material substrate 22.

In one embodiment, a number of layers of the first circuit layer 211 of the first organic material substrate 21 is equal to the number of layers of the second circuit layer 221 of the second organic material substrate 22.

In one embodiment, a heat sink 23 is arranged on the first organic material substrate 21.

In one embodiment, the supporting bodies 24 are electrically connected to the first organic material substrate 21 and the second organic material substrate 22.

In one embodiment, the electronic package 2, 3 further comprises a circuit board 26 on which the second organic material substrate 22 is stacked by a plurality of conductive elements 25. For example, the conductive elements 25 are electrically connected to the circuit board 26 and the second organic material substrate 22.

To sum up, in the electronic package and the manufacturing method thereof according to the present disclosure, by configuring a circuit expected to be bonded to the electronic element in the circuit structure, the line width/line spacing of the redistribution layer of the circuit structure is in line with (e.g., conforms with) the line width/line spacing of the electronic element. Therefore, the electronic package of the present disclosure can meet the requirements of miniaturized packaging.

Furthermore, the process yield of the circuit structure, the first organic material substrate and the second organic material substrate is improved by arranging the expected number of circuit layers in the circuit structure, the first organic material substrate and the second organic material substrate, respectively. Therefore, the manufacturing method of the present disclosure can effectively reduce the manufacturing cost and manufacturing time of the electronic package.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. An electronic package, comprising:
a circuit structure provided with a redistribution layer and having a first surface and a second surface opposite to each other;
at least one electronic element disposed on the first surface of the circuit structure and electrically connected to the redistribution layer;
a first organic material substrate disposed on the second surface of the circuit structure and having a first circuit layer; and
at least one second organic material substrate having a second circuit layer, wherein the first organic material substrate is stacked on the at least one second organic material substrate via a plurality of supporting bodies, such that the redistribution layer is electrically connected to the second circuit layer via the first circuit layer, and wherein a line width or line spacing of the redistribution layer of the circuit structure is smaller than a line width or line spacing of the first circuit layer of the first organic material substrate and a line width or line spacing of the second circuit layer of the at least one second organic material substrate.

2. The electronic package of claim 1, wherein a width of the circuit structure is smaller than a width of the first organic material substrate.

3. The electronic package of claim 1, wherein the first organic material substrate is stacked with a plurality of the second organic material substrates, and the line width or line spacing of each of the second organic material substrates increases in a direction away from the circuit structure.

4. The electronic package of claim 1, wherein the first organic material substrate is stacked with a plurality of the second organic material substrates, and a coefficient of thermal expansion of each of the second organic material substrates increases in a direction away from the circuit structure.

5. The electronic package of claim 1, wherein a number of layers of the redistribution layer of the circuit structure is smaller than a number of layers of the second circuit layer of the at least one second organic material substrate.

6. The electronic package of claim 1, wherein a number of layers of the first circuit layer of the first organic material substrate is equal to a number of layers of the second circuit layer of the at least one second organic material substrate.

7. The electronic package of claim 1, further comprising a heat sink disposed on the first organic material substrate.

8. The electronic package of claim 1, wherein the plurality of supporting bodies are electrically connected to the first organic material substrate and the at least one second organic material substrate.

9. The electronic package of claim 1, further comprising a circuit board, wherein the at least one second organic material substrate is stacked on the circuit board via a plurality of conductive elements.

10. The electronic package of claim 9, wherein the plurality of conductive elements are electrically connected to the circuit board and the at least one second organic material substrate.

11. An electronic package, comprising:
a circuit structure provided with a redistribution layer and having a first surface and a second surface opposite to each other;
at least one electronic element disposed on the first surface of the circuit structure and electrically connected to the redistribution layer;
a first organic material substrate disposed on the second surface of the circuit structure and having a first circuit layer; and
at least one second organic material substrate having a second circuit layer, wherein the first organic material substrate is stacked on the at least one second organic material substrate via a plurality of supporting bodies, such that the redistribution layer is electrically connected to the second circuit layer via the first circuit layer, and wherein a coefficient of thermal expansion of the at least one second organic material substrate is greater than a coefficient of thermal expansion of the circuit structure and a coefficient of thermal expansion of the first organic material substrate.

12. The electronic package of claim 11, wherein a width of the circuit structure is smaller than a width of the first organic material substrate.

13. The electronic package of claim 11, wherein the first organic material substrate is stacked with a plurality of the second organic material substrates, and a line width or line spacing of each of the second organic material substrates increases in a direction away from the circuit structure.

14. The electronic package of claim 11, wherein the first organic material substrate is stacked with a plurality of the second organic material substrates, and the coefficient of thermal expansion of each of the second organic material substrates increases in a direction away from the circuit structure.

15. The electronic package of claim 11, wherein a number of layers of the redistribution layer of the circuit structure is smaller than a number of layers of the second circuit layer of the at least one second organic material substrate.

16. The electronic package of claim 11, wherein a number of layers of the first circuit layer of the first organic material substrate is equal to a number of layers of the second circuit layer of the at least one second organic material substrate.

17. The electronic package of claim 11, further comprising a heat sink disposed on the first organic material substrate.

18. The electronic package of claim 11, wherein the plurality of supporting bodies are electrically connected to the first organic material substrate and the at least one second organic material substrate.

19. The electronic package of claim 11, further comprising a circuit board, wherein the at least one second organic material substrate is stacked on the circuit board via a plurality of conductive elements.

20. The electronic package of claim 19, wherein the plurality of conductive elements are electrically connected to the circuit board and the at least one second organic material substrate.

21. A method of manufacturing an electronic package, comprising:
providing a circuit structure with a redistribution layer, a first organic material substrate with a first circuit layer and at least one second organic material substrate with a second circuit layer, wherein the circuit structure has a first surface and a second surface opposite to each other, and a line width or line spacing of the redistribution layer of the circuit structure is smaller than a line width or line spacing of the first circuit layer of the first organic material substrate and a line width or line spacing of the second circuit layer of the at least one second organic material substrate;
disposing at least one electronic element on the first surface of the circuit structure and electrically connecting the at least one electronic element to the redistribution layer, and disposing the first organic material substrate on the second surface of the circuit structure; and
stacking the first organic material substrate on the at least one second organic material substrate via a plurality of supporting bodies, wherein the redistribution layer is electrically connected to the second circuit layer via the first circuit layer.

22. The method of claim 21, wherein a width of the circuit structure is smaller than a width of the first organic material substrate.

23. The method of claim 21, wherein the first organic material substrate is stacked with a plurality of the second organic material substrates, and the line width or line spacing of each of the second organic material substrates increases in a direction away from the circuit structure.

24. The method of claim 21, wherein the first organic material substrate is stacked with a plurality of the second organic material substrates, and a coefficient of thermal expansion of each of the second organic material substrates increases in a direction away from the circuit structure.

25. The method of claim 21, wherein a number of layers of the redistribution layer of the circuit structure is smaller than a number of layers of the second circuit layer of the at least one second organic material substrate.

26. The method of claim 21, wherein a number of layers of the first circuit layer of the first organic material substrate is equal to a number of layers of the second circuit layer of the at least one second organic material substrate.

27. The method of claim 21, further comprising disposing a heat sink on the first organic material substrate.

28. The method of claim 21, wherein the plurality of supporting bodies are electrically connected to the first organic material substrate and the at least one second organic material substrate.

29. The method of claim 21, further comprising providing a circuit board, wherein the at least one second organic material substrate is stacked on the circuit board via a plurality of conductive elements.

30. The method of claim 29, wherein the plurality of conductive elements are electrically connected to the circuit board and the at least one second organic material substrate.

31. A method of manufacturing an electronic package, comprising:
providing a circuit structure with a redistribution layer, a first organic material substrate with a first circuit layer and at least one second organic material substrate with a second circuit layer, wherein the circuit structure has a first surface and a second surface opposite to each other, and a coefficient of thermal expansion of the at least one second organic material substrate is greater than a coefficient of thermal expansion of the circuit structure and a coefficient of thermal expansion of the first organic material substrate;
disposing at least one electronic element on the first surface of the circuit structure and electrically connecting the at least one electronic element to the redistribution layer, and disposing the first organic material substrate on the second surface of the circuit structure; and
stacking the first organic material substrate on the at least one second organic material substrate via a plurality of supporting bodies, wherein the redistribution layer is electrically connected to the second circuit layer via the first circuit layer.

32. The method of claim 31, wherein a width of the circuit structure is smaller than a width of the first organic material substrate.

33. The method of claim 31, wherein the first organic material substrate is stacked with a plurality of the second organic material substrates, and a line width or line spacing of each of the second organic material substrates increases in a direction away from the circuit structure.

34. The method of claim 31, wherein the first organic material substrate is stacked with a plurality of the second organic material substrates, and the coefficient of thermal expansion of each of the second organic material substrates increases in a direction away from the circuit structure.

35. The method of claim 31, wherein a number of layers of the redistribution layer of the circuit structure is smaller than a number of layers of the second circuit layer of the at least one second organic material substrate.

36. The method of claim 31, wherein a number of layers of the first circuit layer of the first organic material substrate is equal to a number of layers of the second circuit layer of the at least one second organic material substrate.

37. The method of claim 31, further comprising disposing a heat sink on the first organic material substrate.

38. The method of claim 31, wherein the plurality of supporting bodies are electrically connected to the first organic material substrate and the at least one second organic material substrate.

39. The method of claim 31, further comprising providing a circuit board, wherein the at least one second organic material substrate is stacked on the circuit board via a plurality of conductive elements.

40. The method of claim 39, wherein the plurality of conductive elements are electrically connected to the circuit board and the at least one second organic material substrate.
